(19) United States
(12) Patent Application Publication
(10) Pub. No.: US 2025/0070067 A1
(43) Pub. Date: Feb. 27, 2025

(54) ENABLING MICRO-BUMP ARCHITECTURES WITHOUT THE USE OF SACRIFICIAL PADS FOR PROBING A WAFER

(71) Applicant: Microsoft Technology Licensing, LLC, Redmond, WA (US)

(72) Inventors: Rahul AGARWAL, Livermore, CA (US); Sriram SRINIVASAN, Chandler, AZ (US)

(21) Appl. No.: 18/454,657

(22) Filed: Aug. 23, 2023

(51) Int. Cl. H01L 23/00; H01L 21/66

(52) U.S. Cl. CPC H01L 24/11; H01L 22/32; H01L 24/14; H01L 2224/11019; H01L 2224/11602; H01L 2224/11901; H01L 2224/1403; H01L 2224/14133; H01L 2924/3025

(57) ABSTRACT

Methods for enabling micro-bump architectures without the use of sacrificial pads for probing a wafer are described. A method includes forming: (1) a first bump in accordance with a specified first diameter, and (2) a first set of bumps in accordance with a specified second diameter, smaller than the specified first diameter. The first bump is used for probing a portion of the wafer associated with the first set of bumps. Both the first bump and the first set of bumps are then removed. The method includes forming: (1) a second set of bumps, in place of the first bump, where each of the second set of bumps is formed in accordance with the specified second diameter, and (2) a third set of bumps, in place of the first set of bumps, where each of the third set of bumps is formed in accordance with the specified second diameter.

### BACKGROUND

Increasingly, computing and communication systems include dies interconnected via interposers. As an example, chiplets or dies may be stacked side by side on a passive interposer or an active interposer. Alternatively, one or more memory dies may be stacked on a logic die. Multiple logic dies may also be stacked on top of each other. In other arrangement, a mix of logic dies and memory dies is used and they may use an interposer.

In many such arrangements, there is a need for high bandwidth connections between the logic die and the memory die. Bumps with smaller critical dimensions (e.g., micro-bumps) are used to attach the chiplets or dies to interposers. During the manufacturing of such systems, micro-bumps formed on wafers require probing. Current probing technology for testing known-good-dies (KGDs) is not mature enough to probe micro-bumps. This is because they are small and delicate, and thus probing may damage them. In addition, higher density micro-bumps are harder to probe using conventional probes used for probing bigger bumps, such as C4 bumps.

To address these issues, a common solution has been the use of sacrificial (SAC) pads. The SAC pads are formed along with the micro-bumps and probing is performed using the SAC pads instead of the micro-bumps. The SAC pads are used for probing purposes only and offer no other device functionality. SAC pads consume a significant amount of area on the die. In addition, there may be a large amount of keep-out area surrounding each SAC pad to allow easy access using a probe. This results in potentially wasted silicon area on the die.

Accordingly, there is a need for improved methods and systems for enabling micro-bump architectures that do not require the presence of SAC pads.

### SUMMARY

In one example, the present disclosure relates to a method including forming: (1) a first bump on a substrate of a wafer, where the first bump is formed in accordance with a specified first diameter, and (2) a first set of bumps on the substrate of the wafer, where each of the first set of bumps is formed in accordance with a specified second diameter, smaller than the specified first diameter. The method may further include using the first bump, probing a portion of the wafer that is associated with one or more of the first set of bumps.

The method may further include removing material associated with both the first bump and the first set of bumps to allow for re-formation of bumps in place of the first bump and the first set of bumps. The method may further include forming: (1) a second set of bumps, in place of the first bump, where each of the second set of bumps is formed in accordance with the specified second diameter, and (2) a third set of bumps, in place of the first set of bumps, where each of the third set of bumps is formed in accordance with the specified second diameter.

In another example, the present disclosure relates to a method including forming: (1) a first bump on a substrate of a wafer, where the first bump is formed in accordance with a specified first diameter, and (2) a first set of bumps on the substrate of the wafer, where each of the first set of bumps is formed in accordance with a specified second diameter, smaller than the specified first diameter. The method may further include using the first bump, probing a portion of the wafer that is associated with one or more of the first set of bumps.

The method may further include forming a protective layer over the first bump and the first set of bumps. The method may further include removing material associated with the protective layer and both the first bump and the first set of bumps to allow for re-formation of bumps in place of the first bump and the first set of bumps. The method may further include forming: (1) a second set of bumps, in place of the first bump, where each of the second set of bumps is formed in accordance with the specified second diameter and (2) a third set of bumps, in place of the first set of bumps, where each of the third set of bumps is formed in accordance with the specified second diameter.

In yet another example, the present disclosure relates to a method including forming: (1) a first bump on a substrate of a wafer, where the first bump is formed in accordance with a specified first diameter, and (2) a first set of bumps on the substrate of the wafer, where each of the first set of bumps is formed in accordance with a specified second diameter, smaller than the specified first diameter. The method may further include using the first bump, probing a portion of the wafer that is associated with one or more of the first set of bumps.

The method may further include forming a protective layer over the first bump and the first set of bumps. The method may further include removing material associated with the protective layer and both the first bump and the first set of bumps to allow for re-formation of bumps in place of the first bump and the first set of bumps. The method may further include forming: (1) a second set of bumps, in place of the first bump, where each of the second set of bumps is formed in accordance with the specified second diameter and a specified first height, and where each of the second set of bumps is associated with a first active circuitry formed as part of the wafer, and (2) a third set of bumps, in place of the first set of bumps, where each of the third set of bumps is formed in accordance with the specified second diameter and the specified first height, and where each of the second set of bumps is associated with a second active circuitry, different from the first active circuitry, formed as part of the wafer.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows a view of a wafer during a fabrication stage in accordance with one example;

FIG. 2 shows a view of a wafer during a fabrication stage in accordance with one example;

FIG. 3 shows a layout of the bumps on a wafer for probing in accordance with one example;

FIG. 4 shows a view of a wafer during a fabrication stage in accordance with one example;

FIG. 5 shows a view of a wafer during a fabrication stage in accordance with one example;

FIG. 6 shows a view of a wafer during a fabrication stage in accordance with one example;

FIG. 7 shows a bottom view of an example die that has been formed after severing the wafer into multiple dies; and

FIG. 8 shows a flow chart of a method for probing bumps and nets formed in a wafer in accordance with one example.

### DETAILED DESCRIPTION

Examples described in this disclosure relate to methods for enabling micro-bump architectures without the use of sacrificial pads for probing a wafer. As explained earlier, in many computing systems there is a need for high bandwidth connections between the logic die and the memory die. Bumps with smaller critical dimensions (e.g., micro-bumps) are used to attach the chiplets or dies to interposers.

Current probing technology for testing known-good-dies (KGDs) is not mature enough to probe wafers with micro-bumps. This is because the micro-bumps are small (e.g., less than 30 microns in diameter) and delicate, and thus probing may damage them. In addition, higher density micro-bumps are harder to probe using conventional probes used for probing bigger bumps, such as C4 bumps. Additionally, because micro-bumps have smaller critical dimensions, they have a smaller amount of solder as part of the solder caps. If the solder is damaged during probing, then the bonding with the damaged micro-bump is less reliable. As an example, micro-bumps with damage to the solder are more likely to have electrical issues, such as opens.

To address these issues, a common solution has been the use of sacrificial (SAC) pads. The SAC pads are formed along with the micro-bumps and probing is performed using the SAC pads instead of the micro-bumps. As noted earlier, the SAC pads are used for probing purposes only and offer no other device functionality. SAC pads consume a significant amount of area on the die. In addition, there may be a large amount of keep-out area surrounding each SAC pad to allow easy access using a probe. Advantageously, as part of the processes described herein no sacrificial pads are formed to perform the probe testing.

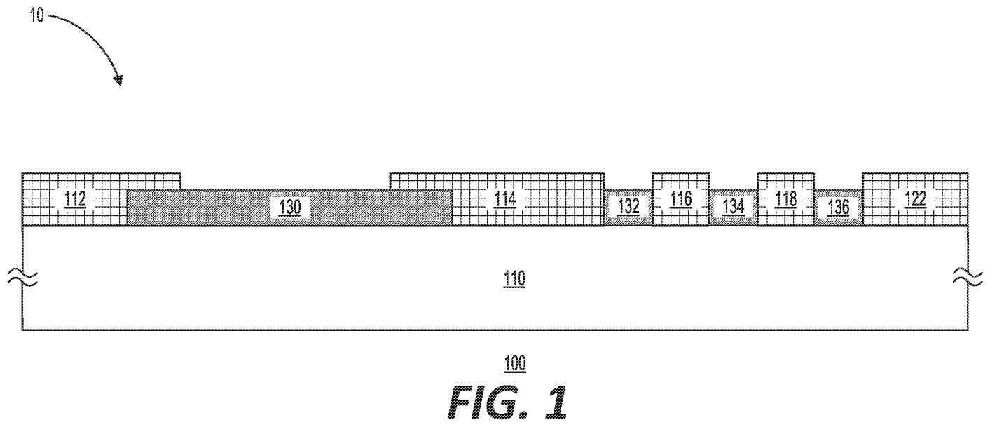

FIG. 1 shows a view 100 of a wafer 10 during a fabrication stage in accordance with one example. Wafer 10 includes a silicon substrate 110. During this fabrication stage, as shown in view 100, wafer 10 further includes passivation layer portions 112, 114, 116, 118, and 122 that are formed on silicon substrate 110. Passivation layer portions 112, 114, 116, 118, and 122 are the remaining portions of the passivation layer, which had been formed on the entire surface of the wafer to protect the entire surface of the wafer. In one example, the passivation layer may be comprised of silicon nitride or silicon oxide.

With continued reference to FIG. 1, view 100 of wafer 10 further shows contact pads 130, 132, 134, and 136 formed on silicon substrate 110. Contact pads 130, 132, 134, and 136 relate to the sites on which interconnection structures, such as bumps, may be formed. Although FIG. 1 shows wafer 10 with a certain number of layers and components arranged in a certain manner there could be more or fewer number of layers or components, which could be arranged differently.

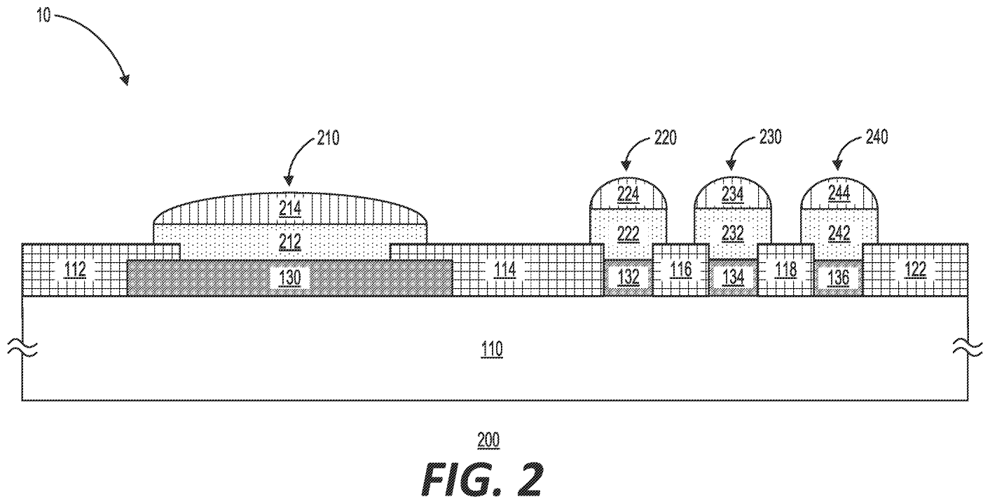

FIG. 2 shows a view 200 of wafer 10 during a fabrication stage in accordance with one example. Unless indicated otherwise, the same or similar layers and components that are shown in FIG. 2 are referred to using the same reference numbers as used in the previous figures (e.g., FIG. 1). As part of view 200, bumps 210, 220, 230, and 240 are shown as part of wafer 10. Each bump includes a metal layer (e.g., a plated copper layer) formed on wafer 10. As an example, bump 210 includes a metal layer 212, bump 220 includes a metal layer 222, bump 230 includes a metal layer 232, and bump 240 incudes a metal layer 242. In this example, each of these metal layer is formed by plating copper. Additionally, view 200 shows solder caps formed for each of the bumps. As an example, solder cap 214 is shown as part of bump 210, solder cap 224 is shown as part of bump 220, solder cap 234 is shown as part of bump 230, and solder cap 244 is shown as part of bump 240.

With continued reference to FIG. 2, in one example, bumps 210, 220, 230, and 240 are formed using several steps. In this example, the first step includes barrier/seed sputtering over wafer 10. The formation of the barrier prevents the migration of any metal into the silicon areas of the wafer. Materials such as tantalum, tantalum nitride, titanium, or titanium nitride may be used to form the barrier layer. Next, assuming the micro-bumps are built using copper, copper seed layer is formed using physical vapor deposition or chemical vapor deposition. In another example, the combination of the barrier/seed materials may correspond to under-bump metallurgy (UBM).

As part of the next step, a light-sensitive material (e.g., a photoresist) is applied on top of the sputtered UBM. The next step includes lithography to pattern the areas on wafer 10 corresponding to the bumps for further processing. The next step includes plating of a metal, such as copper. The plating may be performed using the electroplating process. This step results in the formation of metal layers 212, 222, 232, and 242 shown in FIG. 2. The next step includes stripping of the photoresist.

The next step includes etching of the barrier/seed material from wafer 10. Finally, solder material is reflowed to form the caps (e.g., solder caps 214, 224, 234, and 244). Micro-bumps 220, 230, and 240 may have a diameter of less than or equal to 30 microns and a pitch of less than or equal to 55 microns. Although FIG. 2 shows wafer 10 with a certain number of layers and components arranged in a certain manner there could be more or fewer number of layers or components, which could be arranged differently. As an example, although solder caps 214, 224, 234, and 244 are shown as part of the bumps, these solder caps may not be required. As an example, in a manufacturing process where the metal layers for the bumps are formed using gold (Au), then the solder caps may be omitted as part of the process. As another example, even when the metal layers are formed using copper, the solder caps may be omitted at this stage. This is because in some instances probing could be performed without the need for solder caps. In addition, instead of bump 210 being a C4 bump, it could be formed as another type of contact for probing.

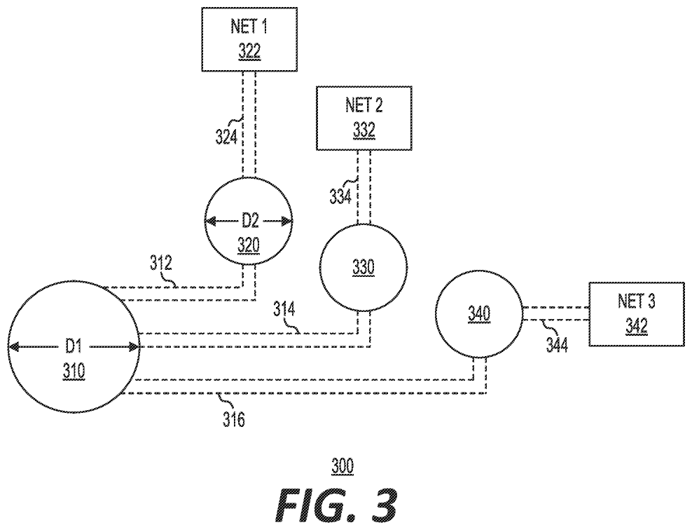

FIG. 3 shows a layout 300 of the bumps on a wafer for probing in accordance with one example. Layout 300 is merely an example and the bumps for probing may be laid out differently. Layout 300 shows four bumps 310, 320, 330, and 340. Bump 310 corresponds to a bump similar to bump 210 described earlier with respect to FIG. 2. Bumps 320, 330, and 340 correspond to micro-bumps similar to bumps 220, 230, and 240 described earlier with respect to FIG. 2. Thus, in this example, bump 310 has been formed based on a specified diameter (D1) and each of bumps 320, 330, and 340 has been formed based on a different specified diameter (D2), such that diameter D1 is larger than diameter D2. Bump 310 is coupled via a trace 312 to bump 320. Bump 310 is coupled via a trace 314 to bump 330. Bump 310 is coupled via a trace 316 to bump 340. Although layout 300 of FIG. 3 shows a direct coupling between bump 310 and bumps 320, 330, and 340, they may be coupled indirectly via other structures or metal layers. In addition, layout 300 shows a NET 1 322 coupled to bump 320 via trace 324. NET 2 332 is coupled to bump 330 via trace 334. NET 3 342 is coupled to bump 340 via trace 344. A net that is being tested via a bump comprises of one or more bumps and the interconnects in-between. A net, which is one or more connections or pairing among bumps, can be probed using the same probe bump (e.g., bump 310). In sum, the net represents a portion of the wafer that is being tested.

The routing of bumps to micro-bumps or other types of bumps being probed need not be simple and linear as shown in FIG. 3. Instead, bump 310, which is making a contact with the probe, may have routed connections to other micro-bumps included in various nets. A probe associated with an integrated circuit prober (IC prober) can be used to make a contact with bump 310 in order to test any of the nets shown in layout 300. The IC prober may further be coupled to an IC tester, which allows one to run various types of tests for testing the nets shown in layout 300.

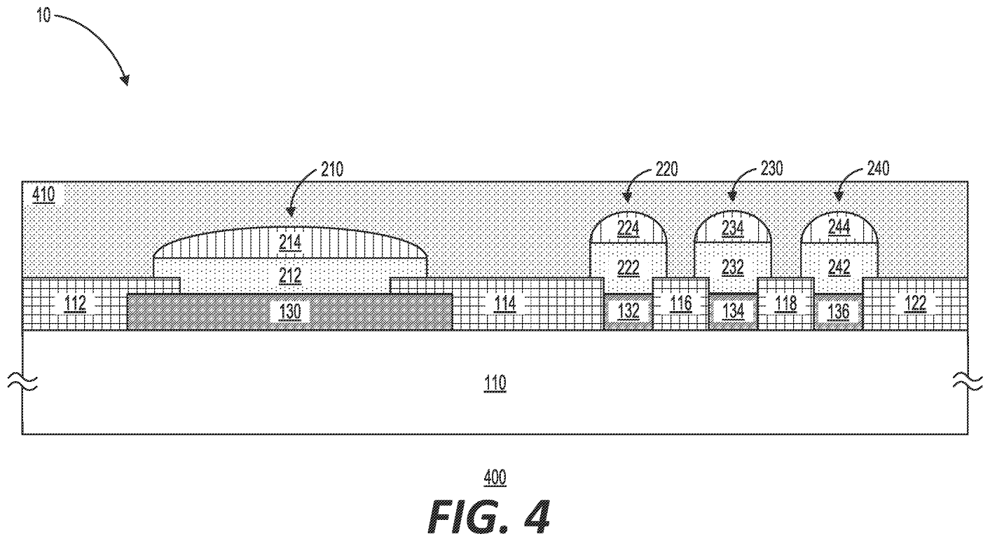

The tests may relate to wafer/device testing, including tests to determine whether the die is a good die in terms of no presence of any opens or shorts along the various nets being tested. As an example, automated test equipment (ATE) may be connected to an IC prober, which may have probes in direct contact with bumps for testing. The probes may provide voltage for testing to the bumps to test for any defects in the wafer. Advantageously, no sacrificial pads are formed to perform the probe testing. Instead, as explained further after the probe testing is completed, additional steps are performed to remove the material associated with probes 310, 320, 330, and 340, and form new bumps (e.g., micro-bumps) as described later with respect to FIGS. 4-6.

FIG. 4 shows a view 400 of wafer 10 during a fabrication stage in accordance with one example. Unless indicated otherwise, the same or similar layers and components that are shown in FIG. 4 are referred to using the same reference numbers as used in the previous figures (e.g., FIGS. 1 and 2). During this manufacturing stage, wafer 10 is coated using a protective layer 410 to protect wafer 10. Protective layer 410 may be a polyimide layer or a polybenzoxazole (PBO) layer. Protective layer 410 provides protection to the components and the layers formed as part of wafer 10 during the next steps that include removal of certain material. Although FIG. 4 shows wafer 10 with a certain number of layers and components arranged in a certain manner there could be more or fewer number of layers or components, which could be arranged differently.

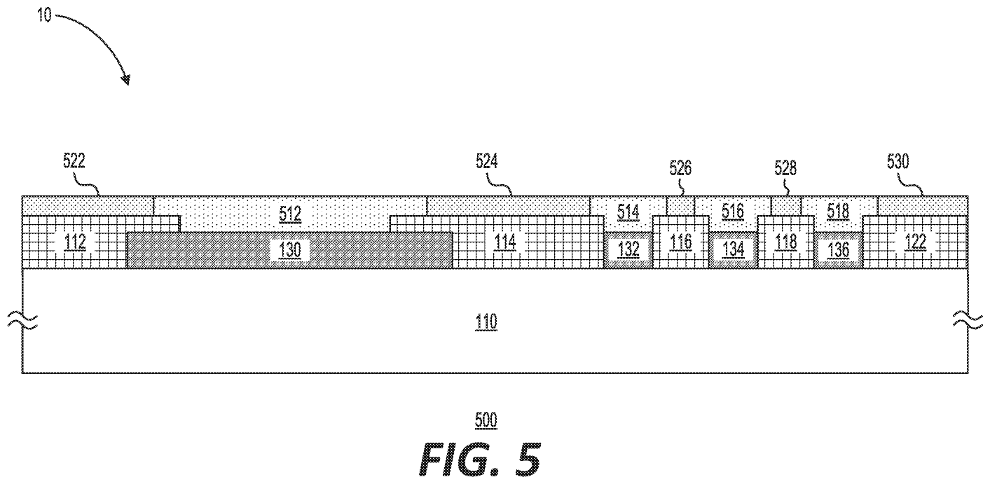

FIG. 5 shows a view of a wafer during a fabrication stage in accordance with one example. Unless indicated otherwise, the same or similar layers and components that are shown in FIG. 5 are referred to using the same reference numbers as used in the previous figures (e.g., FIGS. 1, 2, and 4). During this fabrication stage, the material corresponding to protective layer 410, solder caps 214, 224, 234, and 244, and portions of metal layers 212, 222, 232, and 234 are removed. The removal of the material may be accomplished by grinding the surface. Alternatively, the material corresponding to protective layer 410, solder caps 214, 224, 234, and 244, and portions of metal layers 212, 222, 232, and 234 may be removed by cutting or sawing. The remaining surface may be smoothed using chemical-mechanical polishing.

As shown in FIG. 5, wafer 10 is now left with portions of protective layer 410, including portions 522, 524, 526, 528, and 530. In addition, at this fabrication stage, view 500 shows metal layer portions 512, 514, 516, and 518. These metal layer portions correspond to the location of the bumps that had been formed prior to the probing of the circuits in wafer 10. Although FIG. 5 shows wafer 10 with a certain number of layers and components arranged in a certain manner there could be more or fewer number of layers or components, which could be arranged differently.

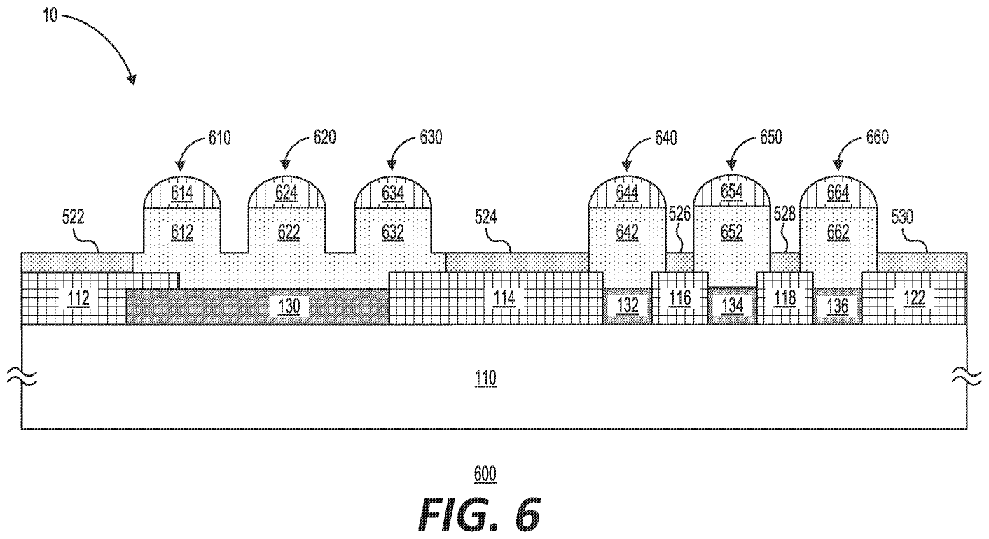

FIG. 6 shows a view of a wafer during a fabrication stage in accordance with one example. Unless indicated otherwise, the same or similar layers and components that are shown in FIG. 5 are referred to using the same reference numbers as used in the previous figures (e.g., FIGS. 1, 2, 4, and 5). In view 600, bumps 610, 620, 630, 640, 650, and 660 are shown as part of wafer 10. Each of these bumps are formed based on the same specified diameter and specified height. As an example, each of these bumps is a micro-bump. Bumps 610, 620, and 630 are formed in place of bump 210 of FIG. 2. Micro-bumps having a smaller surface area in contact with a contact pad may cause more problems associated with the electromigration-induced damage at the interface between the contact pad and the copper metal layer. Advantageously, the formation of multiple micro-bumps in place of a larger bump (e.g., bump 210 of FIG. 2) allows one to maintain the same size pad (e.g., contact pad 130) as before. Thus, both FIG. 2 and FIG. 6 show contact pad 130 having a large surface area. This is because multiple micro-bumps (e.g., bumps 610, 620, and 630) are formed on a shared contact pad 130, resulting in the surface area between the metal (e.g., copper) associated with these micro-bumps and contact pad 130 staying almost as large as the surface area between the larger bump (e.g., bump 210) and contact pad 130.

Having this larger surface area for the contact pads allows the re-use of existing silicon IP that may have been designed to work with contact pads having area that is commensurate with the size of a larger bump (e.g., a C4 bump). In other words, silicon IP designed to work with larger bumps need not be redesigned to have smaller contact pads that can work with micro-bumps, and thereby saving the cost of redesigning such silicon IP. Moreover, having this larger surface area helps mitigate electromigration-induced damage with respect to the interface between the contact pad 130 and bump 210. Bumps 640, 650, and 660 are formed in place of bumps 220, 230, and 240 of FIG. 2.

Each bump includes a metal layer (e.g., a plated copper layer) formed on wafer 10. As an example, bump 610 includes a metal layer 612, bump 620 includes a metal layer 622, bump 630 includes a metal layer 632, bump 640 incudes a metal layer 642, bump 650 includes a metal layer 652, and bump 660 incudes a metal layer 662. In this example, these metal layers are formed by plating copper. Additionally, view 600 shows solder caps formed for each of the bumps. As an example, solder cap 614 is shown as part of bump 610, solder cap 624 is shown as part of bump 620, solder cap 634 is shown as part of bump 630, solder cap 644 is shown as part of bump 640, solder cap 654 is shown as part of bump 650, solder cap 664 is shown as part of bump 660.

With continued reference to FIG. 6, in one example, bumps 610, 620, 630, 640, 650, and 660 are formed using several steps. In this example, the first step includes barrier/seed sputtering over wafer 10. The formation of the barrier prevents the migration of any metal into the silicon areas of the wafer. Materials such as tantalum, tantalum nitride, titanium, or titanium nitride may be used to form the barrier layer. Next, assuming the micro-bumps are built using copper, copper seed layer is formed using physical vapor deposition or chemical vapor deposition. In another example, the combination of the barrier/seed materials may correspond to under-bump metallurgy (UBM). As part of the next step, a light sensitive material (e.g., a photoresist) is applied on top of the sputtered UBM. The next step includes lithography to pattern the areas on wafer 10 corresponding to the bumps for further processing. The next step includes plating of a metal, such as copper. The plating may be performed using the electroplating process. This step results in the formation of metal layers 612, 622, 632, 642, 652, and 662 shown in FIG. 6. The next step includes stripping of the photoresist.

The next step includes etching of the barrier/seed material from wafer 10. Finally, solder material is reflowed to form the caps (e.g., solder caps 614, 624, 634, 644, 654, and 664). Micro-bumps 610, 620, 630, 640, 650, and 660 may have a diameter of less than or equal to 30 microns and a pitch of less than or equal to 55 microns. Although FIG. 6 shows wafer 10 with a certain number of layers and components arranged in a certain manner there could be more or fewer number of layers or components, which could be arranged differently. Similarly, bumps 610, 620, 630, 640, 650, and 660 need not be formed as micro-bumps. Instead, they could be other types of interconnect structures, such as hybrid bonds. As another example, although solder caps 614, 624, 634, 644, 654, and 664 are shown as part of the bumps, these solder caps may not be required. As an example, in a manufacturing process where the metal layers for the bumps are formed using gold (Au), then the solder caps may be omitted as part of the process.

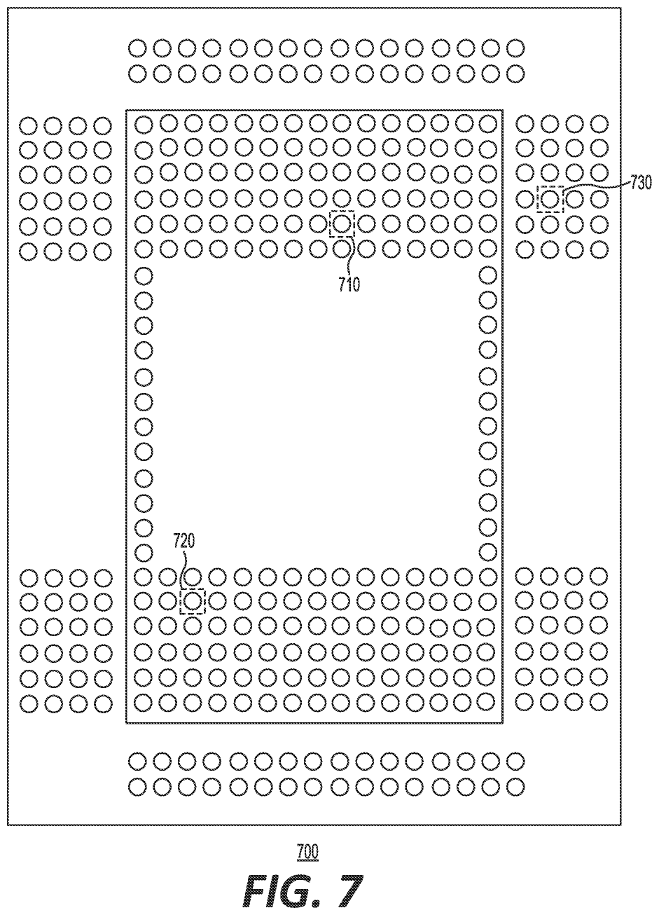

FIG. 7 shows a bottom view of an example die 700 that has been formed after severing the wafer (e.g., wafer 10) into multiple dies. Thus, die 700 is one of multiple dies that may be obtained after wafer 10 has been fully-processed and tested. Die 700 includes a core region (the region inside the inner rectangle) and a peripheral region (the region outside the core region). Each of the regions include several arrays of micro-bumps. As explained above, the process described with respect to FIGS. 1, 2, and 4-6 does not require formation of sacrificial pads for probing the wafer. Thus, in the absence of the above described methodology for probing the wafer, die 700 may include several sacrificial pads. The presence of such sacrificial pads would prevent the formation of micro-bumps not only in the areas where these sacrificial pads are located but also in a keep-out region beyond the sacrificial pads. This would prevent utilization of the silicon area being consumed by the sacrificial pads and the associated keep-out regions. Examples of such potentially wasted silicon areas that would have been occupied by the sacrificial pads are identified via dotted rectangles 710, 720, and 730. The sacrificial pads would have been required to be placed in other locations, as well, and thus these dotted rectangles are merely an illustrative example of some of the potential waste of silicon area.

In addition, many die have metal-insulator-metal (MiM) capacitors for use with those areas of the die that include high-performance mixed signal and/or high-frequency circuits. Having MiM capacitors allows a chip-designer to include capacitors that have high quality factors (Q) and low area consumption. Despite these advantages, MiM capacitors cannot be formed in the areas of die that include the micro-bumps or the sacrificial pads. Advantageously, having no sacrificial pads for probing only as part of die 700 allows better placement and use of MiM capacitors for the die that include high-performance mixed signal and/or high-frequency circuits. Although FIG. 7 shows die 700 with a certain arrangement of micro-bumps there could be more or fewer micro-bumps, which could be arranged differently.

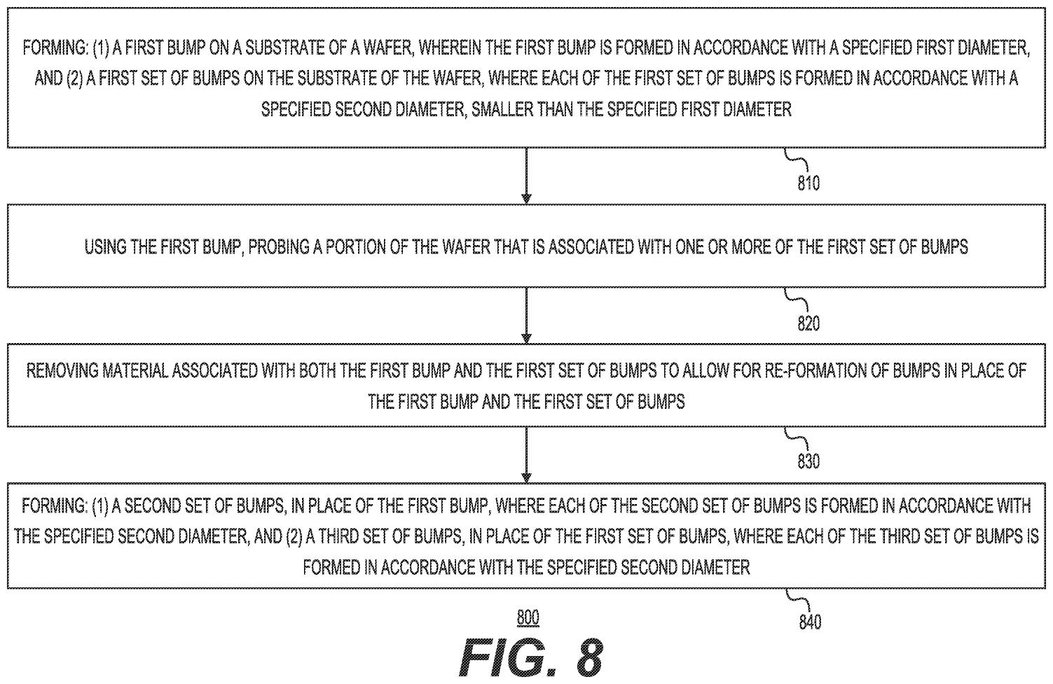

FIG. 8 shows a flow chart 800 of a method for probing bumps and nets formed in wafer 10 in accordance with one example. Step 810 includes forming: (1) a first bump on a substrate of a wafer, where the first bump is formed in accordance with a specified first diameter, and (2) a first set of bumps on the substrate of the wafer, where each of the first set of bumps is formed in accordance with a specified second diameter, smaller than the specified first diameter. In one example, the process steps described earlier with respect to FIGS. 1 and 2 may be used to perform this step. Thus, as part of this step, the first bump may correspond to bump 210 of FIG. 2 and the first set of bumps may correspond to bumps 220, 230, and 240 of FIG. 2. As explained earlier, bump 210 has a larger diameter compared with the diameter of bumps 220, 230, and 240, which can be formed as micro-bumps.

Step 820 includes using the first bump, probing a portion of the wafer that is associated with one or more of the first set of bumps. In one example, the methodology described earlier with respect to FIG. 2 and FIG. 3 may be used to perform this step. Thus, as described earlier, nets associated with the micro-bumps may be probed using bump 210 of FIG. 2.

With continued reference to FIG. 8, step 830 includes removing material associated with both the first bump and the first set of bumps to allow for re-formation of bumps in place of the first bump and the first set of bumps. In one example, as described earlier with respect to FIGS. 4 and 5, the material corresponding to protective layer 410 of FIG. 4, solder caps 214, 224, 234, and 244 of FIG. 2, and portions of metal layers 212, 222, 232, and 234 of FIG. 2 are removed. This allows the re-formation of new bumps (e.g., micro-bumps) in place of bump 210 of FIG. 2 and bumps 220, 230, and 240 of FIG. 2.

Step 840 includes forming: (1) a second set of bumps, in place of the first bump, where each of the second set of bumps is formed in accordance with the specified second diameter, and (2) a third set of bumps, in place of the first set of bumps, where each of the third set of bumps is formed in accordance with the specified second diameter. In one example, the process steps described earlier with respect to FIG. 6 may be used to perform this step. Thus, as part of this step, the second set of bumps may correspond to bumps 610, 620, and 630 of FIG. 6 and the third set of bumps may correspond to bumps 640, 650, and 660 of FIG. 6. As explained earlier, each of these bumps can be formed as micro-bumps.

After the completion of these steps, wafer 10 may be diced into separate dies or chiplets. Each die may include both logic and memory. Processing logic may comprise one or more cores or other types of processing logic. Memory may comprise a memory array or several banks of memory arrays. The memory arrays may be implemented as static random access memory (SRAM) arrays. In addition, each SRAM may be implemented as a 2-port SRAM allowing for simultaneous read/write operations via buffers. Other memory technologies may also be used. The dies or chiplets may comprise central processing units (CPUs), application specific integrated circuits (ASICs), graphical processing units (GPUs), field programmable gate arrays (FPGAs), microcontrollers, I/O circuits, Ethernet PHYs, or other silicon IP. Using the micro-bumps formed as part of the processing of wafer 10 above, the separated dies may be combined into various systems with multiple dies. In sum, the dies or chiplets formed from wafer 10 can be implemented in the context of various types of stacking arrangements, including face-to-face (F2F) stacking, face-to-back (F2B) stacking, or back-to-back (B2B) stacking.

In conclusion, the present disclosure relates to a method including forming: (1) a first bump on a substrate of a wafer, where the first bump is formed in accordance with a specified first diameter, and (2) a first set of bumps on the substrate of the wafer, where each of the first set of bumps is formed in accordance with a specified second diameter, smaller than the specified first diameter. The method may further include using the first bump, probing a portion of the wafer that is associated with one or more of the first set of bumps.

The method may further include removing material associated with both the first bump and the first set of bumps to allow for re-formation of bumps in place of the first bump and the first set of bumps. The method may further include forming: (1) a second set of bumps, in place of the first bump, where each of the second set of bumps is formed in accordance with the specified second diameter, and (2) a third set of bumps, in place of the first set of bumps, where each of the third set of bumps is formed in accordance with the specified second diameter.

Each of one the second set of bumps and the third set of bumps may comprise a micro-bump. Each of the second set of bumps and the third set of bumps may be formed in accordance with a same specified height. Removing the material associated with both the first bump and the first set of bumps may comprise polishing, cutting, or grinding the material.

Forming the second set of bumps may comprise forming multiple micro-bumps to maintain a large contact surface between the multiple micro-bumps and a contact pad underlying the micro-bumps. The large contact surface between the multiple micro-bumps and the contact pad underlying the micro-bumps is configured to mitigate effects of any electromigration-induced damage. None of the first set of bumps, the second set of bumps, or the third set of bumps is probed using a sacrificial pad formed on the wafer.

In another example, the present disclosure relates to a method including forming: (1) a first bump on a substrate of a wafer, where the first bump is formed in accordance with a specified first diameter, and (2) a first set of bumps on the substrate of the wafer, where each of the first set of bumps is formed in accordance with a specified second diameter, smaller than the specified first diameter. The method may further include using the first bump, probing a portion of the wafer that is associated with one or more of the first set of bumps.

The method may further include forming a protective layer over the first bump and the first set of bumps. The method may further include removing material associated with the protective layer and both the first bump and the first set of bumps to allow for re-formation of bumps in place of the first bump and the first set of bumps. The method may further include forming: (1) a second set of bumps, in place of the first bump, where each of the second set of bumps is formed in accordance with the specified second diameter and (2) a third set of bumps, in place of the first set of bumps, where each of the third set of bumps is formed in accordance with the specified second diameter.

Each of one the second set of bumps and the third set of bumps may comprise a micro-bump. Each of the second set of bumps and the third set of bumps may be formed in accordance with a same specified height. Removing the material associated with the protective layer and both the first bump and the first set of bumps may comprise polishing, cutting, or grinding the material.

Forming the second set of bumps may comprise forming multiple micro-bumps to maintain a large contact surface between the multiple micro-bumps and a contact pad underlying the micro-bumps. The large contact surface between the multiple micro-bumps and the contact pad underlying the micro-bumps is configured to mitigate effects of any electromigration-induced damage. None of the first set of bumps, the second set of bumps, or the third set of bumps is probed using a sacrificial pad formed on the wafer.

In yet another example, the present disclosure relates to a method including forming: (1) a first bump on a substrate of a wafer, where the first bump is formed in accordance with a specified first diameter, and (2) a first set of bumps on the substrate of the wafer, where each of the first set of bumps is formed in accordance with a specified second diameter, smaller than the specified first diameter. The method may further include using the first bump, probing a portion of the wafer that is associated with one or more of the first set of bumps.

The method may further include forming a protective layer over the first bump and the first set of bumps. The method may further include removing material associated with the protective layer and both the first bump and the first set of bumps to allow for re-formation of bumps in place of the first bump and the first set of bumps. The method may further include forming: (1) a second set of bumps, in place of the first bump, where each of the second set of bumps is formed in accordance with the specified second diameter and a specified first height, and where each of the second set of bumps is associated with a first active circuitry formed as part of the wafer, and (2) a third set of bumps, in place of the first set of bumps, where each of the third set of bumps is formed in accordance with the specified second diameter and the specified first height, and where each of the second set of bumps is associated with a second active circuitry, different from the first active circuitry, formed as part of the wafer.

Each one of the second set of bumps and the third set of bumps may comprise a micro-bump. Removing the material associated with the protective layer and both the first bump and the first set of bumps may comprise polishing, cutting, or grinding the material.

Forming the second set of bumps may comprise forming multiple micro-bumps to maintain a large contact surface between the multiple micro-bumps and a contact pad underlying the micro-bumps. The large contact surface between the multiple micro-bumps and the contact pad underlying the micro-bumps is configured to mitigate effects of any electromigration-induced damage. None of the first set of bumps, the second set of bumps, or the third set of bumps is probed using a sacrificial pad formed on the wafer.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), and System-on-a-Chip systems (SOCs), Complex Programmable Logic Devices (CPLDs). In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A method comprising:
forming: (1) a first bump on a substrate of a wafer, wherein the first bump is formed in accordance with a specified first diameter, and (2) a first set of bumps on the substrate of the wafer, wherein each of the first set of bumps is formed in accordance with a specified second diameter, smaller than the specified first diameter;
using the first bump, probing a portion of the wafer that is associated with one or more of the first set of bumps;
removing material associated with both the first bump and the first set of bumps to allow for re-formation of bumps in place of the first bump and the first set of bumps; and
forming: (1) a second set of bumps, in place of the first bump, wherein each of the second set of bumps is formed in accordance with the specified second diameter, and (2) a third set of bumps, in place of the first set of bumps, wherein each of the third set of bumps is formed in accordance with the specified second diameter.

2. The method of claim 1, wherein each one of the second set of bumps and the third set of bumps comprises a micro-bump.

3. The method of claim 1, wherein each one of the second set of bumps and the third set of bumps is formed in accordance with a same specified height.

4. The method of claim 1, wherein removing the material associated with both the first bump and the first set of bumps comprises polishing, cutting, or grinding the material.

5. The method of claim 1, wherein forming the second set of bumps comprises forming multiple micro-bumps to maintain a large contact surface between the multiple micro-bumps and a contact pad underlying the micro-bumps.

6. The method of claim 5, wherein the large contact surface between the multiple micro-bumps and the contact pad underlying the micro-bumps is configured to mitigate effects of any electromigration-induced damage.

7. The method of claim 1, wherein none of the first set of bumps, the second set of bumps, or the third set of bumps is probed using a sacrificial pad formed on the wafer.

8. A method comprising:
forming: (1) a first bump on a substrate of a wafer, wherein the first bump is formed in accordance with a specified first diameter, and (2) a first set of bumps on the substrate of the wafer, wherein each of the first set of bumps is formed in accordance with a specified second diameter, smaller than the specified first diameter;
using the first bump, probing a portion of the wafer that is associated with one or more of the first set of bumps;
forming a protective layer over the first bump and the first set of bumps;
removing material associated with the protective layer and both the first bump and the first set of bumps to allow for re-formation of bumps in place of the first bump and the first set of bumps; and
forming: (1) a second set of bumps, in place of the first bump, wherein each of the second set of bumps is formed in accordance with the specified second diameter and (2) a third set of bumps, in place of the first set of bumps, wherein each of the third set of bumps is formed in accordance with the specified second diameter.

9. The method of claim 8, wherein each one of the second set of bumps and the third set of bumps comprises a micro-bump.

10. The method of claim 8, wherein each one of the second set of bumps and the third set of bumps is formed in accordance with a same specified height.

11. The method of claim 8, wherein removing the material associated with the protective layer and both the first bump and the first set of bumps comprises polishing, cutting, or grinding the material.

12. The method of claim 8, wherein forming the second set of bumps comprises forming multiple micro-bumps to maintain a large contact surface between the multiple micro-bumps and a contact pad underlying the micro-bumps.

13. The method of claim 12, wherein the large contact surface between the multiple micro-bumps and the contact pad underlying the micro-bumps is configured to mitigate effects of any electromigration-induced damage.

14. The method of claim 8, wherein none of the first set of bumps, the second set of bumps, or the third set of bumps is probed using a sacrificial pad formed on the wafer.

15. A method comprising:
forming: (1) a first bump on a substrate of a wafer, wherein the first bump is formed in accordance with a specified first diameter, and (2) a first set of bumps on the substrate of the wafer, wherein each of the first set of bumps is formed in accordance with a specified second diameter, smaller than the specified first diameter;
using the first bump, probing a portion of the wafer that is associated with one or more of the first set of bumps;
forming a protective layer over the first bump and the first set of bumps;
removing material associated with the protective layer and both the first bump and the first set of bumps to allow for re-formation of bumps in place of the first bump and the first set of bumps; and
forming: (1) a second set of bumps, in place of the first bump, wherein each of the second set of bumps is formed in accordance with the specified second diameter and a specified first height, and wherein each of the second set of bumps is associated with a first active circuitry formed as part of the wafer, and (2) a third set of bumps, in place of the first set of bumps, wherein each of the third set of bumps is formed in accordance with the specified second diameter and the specified first height, and wherein each of the second set of bumps is associated with a second active circuitry, different from the first active circuitry, formed as part of the wafer.

16. The method of claim 15, wherein each one of the second set of bumps and the third set of bumps comprises a micro-bump.

17. The method of claim 15, wherein removing the material associated with the protective layer and both the first bump and the first set of bumps comprises polishing, cutting, or grinding the material.

18. The method of claim 15, wherein forming the second set of bumps comprises forming multiple micro-bumps to maintain a large contact surface between the multiple micro-bumps and a contact pad underlying the micro-bumps.

19. The method of claim 18, wherein the large contact surface between the multiple micro-bumps and the contact pad underlying the micro-bumps is configured to mitigate effects of any electromigration-induced damage.

20. The method of claim 15, wherein none of the first set of bumps, the second set of bumps, or the third set of bumps is probed using a sacrificial pad formed on the wafer.
